(19) United States
(12) Patent Application Publication
(10) Pub. No.: US 2020/0209930 A1
(43) Pub. Date: Jul. 2, 2020

(54) INFORMATION PROCESSING APPARATUS

(71) Applicant: FUJITSU CLIENT COMPUTING LIMITED, Kanagawa (JP)

(72) Inventor: Akira Takeuchi, Kawasaki (JP)

(73) Assignee: FUJITSU CLIENT COMPUTING LIMITED, Kanagawa (JP)

(21) Appl. No.: 16/690,428

(22) Filed: Nov. 21, 2019

(30) Foreign Application Priority Data
Dec. 28, 2018 (JP) 2018-248668

(51) Int. Cl. G06F 1/24; H03K 17/687; G06F 1/26

(52) U.S. Cl. CPC G06F 1/24; G06F 1/26; H03K 17/687

(57) ABSTRACT

An information processing apparatus includes: a control device being reset upon receipt of a reset signal; and a control target device controlled by a signal sent from a terminal of the control device. The control device includes a fourth terminal that, when the control device is reset, is disconnected and is required to maintain signals from a connected terminal of the control target device at a high level. The fourth terminal is connected to a source of a second NMOS transistor. A gate of the second NMOS transistor receives a reset signal with which reset is performed at a state of Low. A drain of the second NMOS transistor is connected to a terminal of the control target device. The apparatus further includes a third pull-up resistor that pulls up an electric potential between the drain of the second NMOS transistor and the terminal of the control target device.

### CROSS-REFERENCE TO RELATED APPLICATIONS

This application is based upon and claims the benefit of priority from Japanese Patent Application No. 2018-248668, filed Dec. 28, 2018, the entire contents of which are incorporated herein by reference.

### TECHNICAL FIELD

Embodiments described herein relate generally to an information processing apparatus.

### BACKGROUND

Examples of I/O functions of control devices, such as a microcomputer, include a watchdog timer (WDT). The watchdog timer is a function to reset compulsorily a control device in the case where the control device goes out of control and does not receive any operation due to the fault of programs or the influence of noise. Moreover, the control device has a function of updating firmware (FW) of the control device. This function causes the control device not to receive any operation during the update. Therefore, during a period under the update, the system control supported by the control device becomes disabled. Moreover, in order to switch between a normal operation mode and a FW update mode, the control device is reset before the start of the FW update and after the completion of the FW update. The control device may be reset by a restart of a power source.

In a system required to operate continuously, it is needed to operate the system continuously even at the time of reset of a control device used for controlling the system.

### SUMMARY

One aspect of an information processing apparatus according to the present disclosure includes: a control device that is reset upon receipt of a reset signal; and a control target device that is controlled by a signal sent from a terminal of the control device. The control device includes a fourth terminal that, when the control device is reset, is disconnected and is required to maintain signals from a connected terminal of the control target device at a high level. The fourth terminal is connected to a source of a second NMOS transistor, the NMOS being a negative-channel metal oxide semiconductor. A gate of the second NMOS transistor receives a reset signal with which reset is performed at a state of Low. A drain of the second NMOS transistor is connected to a terminal of the control target device. The information processing apparatus further comprises a third pull-up resistor that pulls up an electric potential between the drain of the second NMOS transistor and the terminal of the control target device.

Another aspect of the information processing apparatus according to the present disclosure includes: a control device that is reset upon receipt of a reset signal; and a control target device that is controlled by a signal sent from a terminal of the control device. The control device includes a fifth terminal that, when the control device is reset, becomes a state of Low and is required to maintain signals from a connected terminal of the control target device at a low level. The fifth terminal is connected to a gate of a third NMOS transistor, the NMOS being a negative-channel metal oxide semiconductor. A source of the third NMOS transistor is connected to ground. A drain of the third NMOS transistor is connected to a gate of a fourth NMOS transistor. A source of the fourth NMOS transistor is connected to ground. A drain of the fourth NMOS transistor is connected to a terminal of the control target device. The information processing apparatus further comprises: a third pull-down resistor that pulls down an electric potential between the fifth terminal and the gate of the third NMOS transistor; a fourth pull-up resistor that pulls up an electric potential between the drain of the third NMOS transistor and the gate of the fourth NMOS transistor; and a fifth pull-up resistor that pulls up an electric potential between the drain of the fourth NMOS transistor and the terminal of the control target device.

### BRIEF DESCRIPTION OF THE DRAWINGS

FIG. 1 is a diagram illustrating an example of a configuration of an information processing apparatus according to an embodiment;

FIG. 2 is a diagram illustrating a combination of a level of a connection destination and a state of a general-purpose input/output (GPIO) terminal when a microcomputer according to the embodiment is reset;

FIG. 3A is a diagram illustrating a first example of a circuit that connects the microcomputer according to the embodiment and a control target device;

FIG. 3B is a diagram illustrating a state of a terminal of a circuit in FIG. 3A corresponding to each state of the microcomputer according to the embodiment;

FIG. 4A is a diagram illustrating a second example of the circuit that connects the microcomputer according to the embodiment and the control target device;

FIG. 4B is a diagram illustrating a state of a terminal of a circuit in FIG. 4A corresponding to each state of the microcomputer according to the embodiment;

FIG. 5A is a diagram illustrating a third example of the circuit that connects the microcomputer according to the embodiment and the control target device;

FIG. 5B is a diagram illustrating a state of a terminal of a circuit in FIG. 5A corresponding to each state of the microcomputer according to the embodiment;

FIG. 6A is a diagram illustrating a fourth example of the circuit that connects the microcomputer according to the embodiment and the control target device;

FIG. 6B is a diagram illustrating a state of a terminal of a circuit in FIG. 6A corresponding to each state of the microcomputer according to the embodiment;

FIG. 7A is a diagram illustrating a fifth example of the circuit that connects the microcomputer according to the embodiment and the control target device;

FIG. 7B is a diagram illustrating a state of a terminal of a circuit in FIG. 7A corresponding to each state of the microcomputer according to the embodiment; and

FIG. 8 is a diagram illustrating an example of a delay circuit that delays a reset release signal to be input into the microcomputer according to the embodiment.

### DETAILED DESCRIPTION

Hereinafter, the exemplary embodiment of the present disclosure is disclosed. A configuration of the embodiment indicated below and actions and effects attained by the configuration are one example. The present disclosure is implementable also with a configuration other than the configuration disclosed in the following embodiment. Moreover, according to the embodiment of the present disclosure, it is possible to provide at least one of various effects (including also derivative effects) provided by the configuration.

In this connection, in this specification, ordinal numbers are used only to distinguish components, members, parts, positions, directions, and the like and do not indicate order and priority.

Example of Configuration

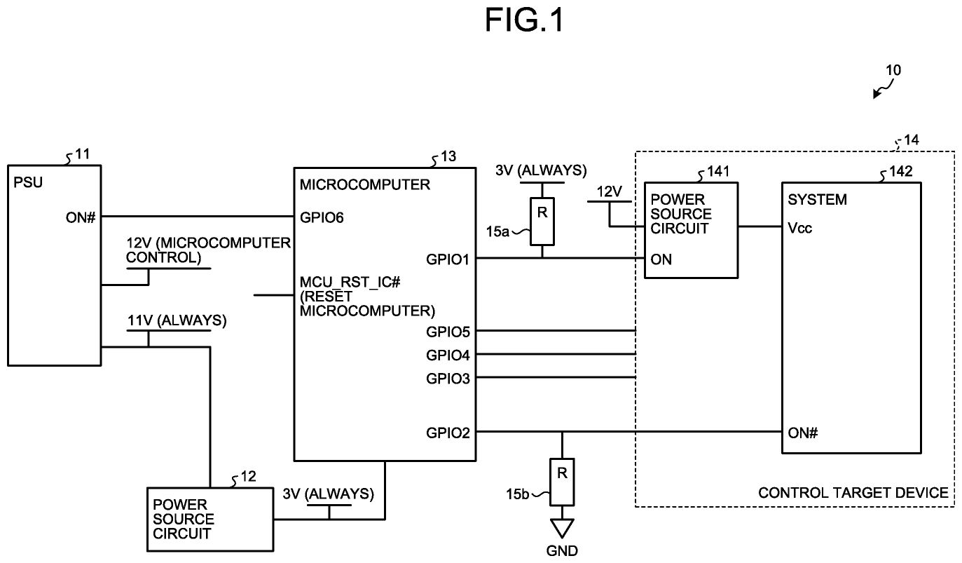

FIG. 1 is a diagram illustrating an example of a configuration of an information processing apparatus 10 according to an embodiment. The information processing apparatus 10 in the embodiment includes a power supply unit (PSU) 11, a power source circuit 12, a microcomputer 13, a control target device 14, and resistors 15a and 15b.

The PSU 11 supplies electric power to devices that are used in the information processing apparatus 10.

The power source circuit 12 converts a voltage of 11 V output from the PSU 11 into a voltage of 3 V and inputs the voltage into the microcomputer 13.

The microcomputer 13 is a control device that controls a control target device 14. The microcomputer 13 operates as, for example, a reset system (a power source control microcomputer) that controls whether to reset the control target device 14. The microcomputer 13 is mounted on, for example, a base substrate of the information processing apparatus 10. The control target device 14 is a device to be controlled. In an example in FIG. 1, the control target device 14 includes a power source circuit 141 and a system 142. The power source circuit 141 inputs a voltage of 12 V into the system 142.

The system 142 is a platform that executes predetermined processing. The system 142 includes, for example, a child substrate mounted on the base substrate. For simplicity, FIG. 1 exemplifies a case where there is provided one system 142. However, there may be provided two or more systems 142.

In the system 142 there is mounted an x86 compatible processor manufactured by Intel, for example. The system 142 is a personal computer (PC) platform on which a general purpose operating system (OS), such as Windows (registered trademark) and Linux (registered trademark), operates.

Moreover, the system 142 is provided with, for example, a processor (an arithmetic processor) suitable for predetermined processing. The predetermined processing is, for example, arithmetic operation with high loads, such as artificial intelligence (AI) interference processing and image processing. The processor suitable for the predetermined processing is, for example, a graphics processing unit (GPU), a field programmable gate array (FPGA), and the like that is available as a device for the PC.

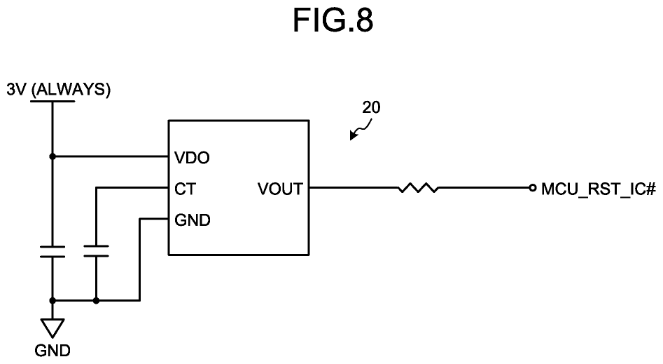

The microcomputer 13 includes a plurality of terminals. In FIG. 1, the terminals of the microcomputer 13 are exemplified by general-purpose input/outputs (GPIO) 1 to 6 and MCU_RST_IC#. The GPIO 1 to 5 are connected to the control target device 14. A resistor 15a is a pull-up resistor to pull up an electric potential at the GPIO1. A resistor 15b is a pull-down resistor to pull down an electric potential at the GPIO2. The GPIO6 is connected to the PSU 11. The MCU_RST_IC# is connected to a delay circuit described later (with referring to FIG. 8).

The MCU_RST_IC# is a terminal to receive a reset signal. Upon receiving a reset signal, the microcomputer 13 is reset. Specifically, for example, when the runaway of the microcomputer 13 occurs, the microcomputer 13 is reset (the MCU_RST_IC# becomes a low level) by a watchdog-timer function. Moreover, for example, at the time of the update of firmware, the microcomputer 13 is reset by the function of a program for update.

In the case where the microcomputer 13 is reset, the program will be re-executed from the initial state. In this case, data on the RAM of the microcomputer 13 and set values for the GPIO1 to GPIO6 are lost. Moreover, because the microcomputer 13 becomes an indefinite state during the reset, the control of the control target device 14 supported by the microcomputer 13 becomes disabled, and it is impossible to keep the state of each of the terminals of the system 142.

Hereinafter, description will be given to a configuration for making it possible to fix a high/low level of a GPIO terminal to a state at the time of the occurrence of reset of the microcomputer 13 even if the microcomputer 13 becomes indefinite. By fixing a level of the GPIO terminal to a state at the time of the occurrence of reset of the microcomputer 13, even when the microcomputer 13 is reset, it is possible to maintain the state of the reset system that controls whether to reset the system 142. Note that the fixing of the microcomputer power source and a high/low level of the GPIO terminal is performed by an always-on power source.

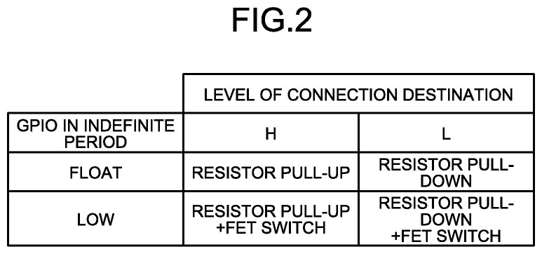

FIG. 2 is a diagram illustrating a combination of a state of a GPIO terminal when the microcomputer 13 in an embodiment is reset and a level of a connection destination. The “H” represents a high level, and the “L” represents a low level. When the microcomputer 13 has been indefinite, the state of the GPIO terminal becomes Float (floating) or low. The level of a terminal of the connection destination of the GPIO terminal is high or low. Therefore, there are four patterns of combinations between the level of the terminal of the connection destination and the state of a GPIO terminal when the microcomputer 13 is reset.

First Pattern (Resistor Pull-Up)

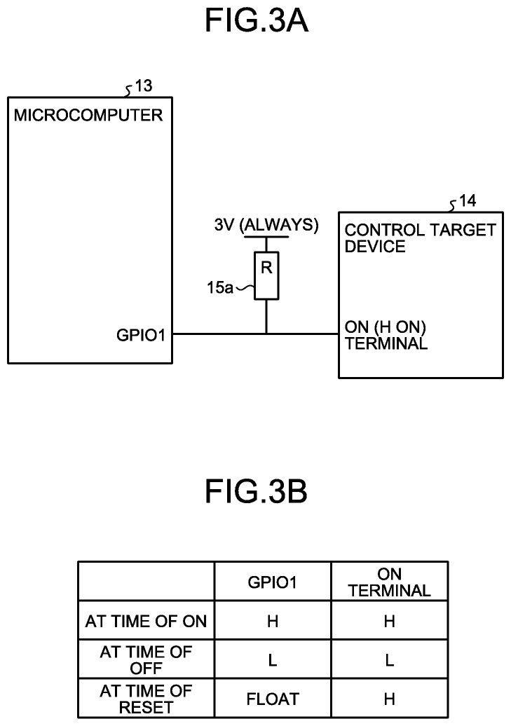

When the GPIO terminal in an indefinite period is in a floating state and the level of the connection destination of the microcomputer 13 at the time of occurrence of reset is a high level, the state is maintained by a pull-up resistor. A circuit in this case is described with the GPIO1 as an example, with reference to FIGS. 3A and 3B.

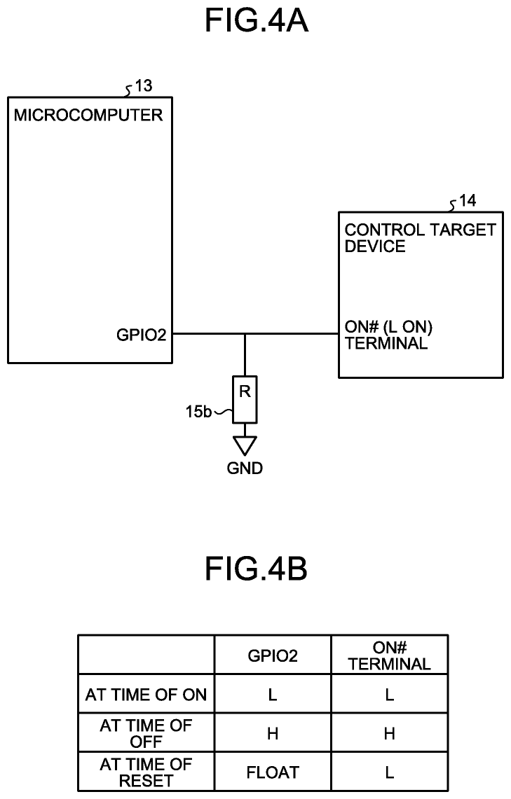

FIG. 3A is a diagram illustrating a first example of a circuit that connects the microcomputer 13 in the embodiment and the control target device 14. When the microcomputer 13 is reset, the GPIO1 (first terminal) becomes a floating state and is required to maintain, at a high level, signals from a connected terminal of the control target device 14. At this time, an electric potential at the GPIO1 is pulled up by a first pull-up resistor 15a. FIG. 3B is a diagram illustrating a state of the terminal of the circuit in FIG. 3A corresponding to each state of the microcomputer 13 in the embodiment. At the time of ON, the microcomputer 13 is operating. At the time of OFF, the microcomputer 13 is stopped. At the time of Reset, the microcomputer 13 is reset. Hereinafter, in FIGS. 4B, 5B, 6B, and 7B, the above definition may be applied similarly.

Second Pattern (Resistor Pull-Down)

When the GPIO terminal in an indefinite period is in a floating state and the level of the connection destination of the microcomputer 13 at the time of occurrence of reset is a low level, the state is maintained by a pull-down resistor. A circuit in this case is described with the GPIO2 as an example, with reference to FIGS. 4A and 4B.

FIG. 4A is a diagram illustrating a second example of the circuit that connects the microcomputer 13 in the embodiment and the control target device 14. When the microcomputer 13 is reset, the GPIO2 (second terminal) becomes a floating state and is required to maintain, at a low level, signals from a connected terminal of the control target device 14. At this time, the electric potential at the GPIO2 is pulled down by a first pull-down resistor 15b. FIG. 4B is a diagram illustrating a state of the terminal in the circuit in FIG. 4A corresponding to each state of the microcomputer 13 in the embodiment.

Third Pattern (Resistor Pull-Up+FET Switch)

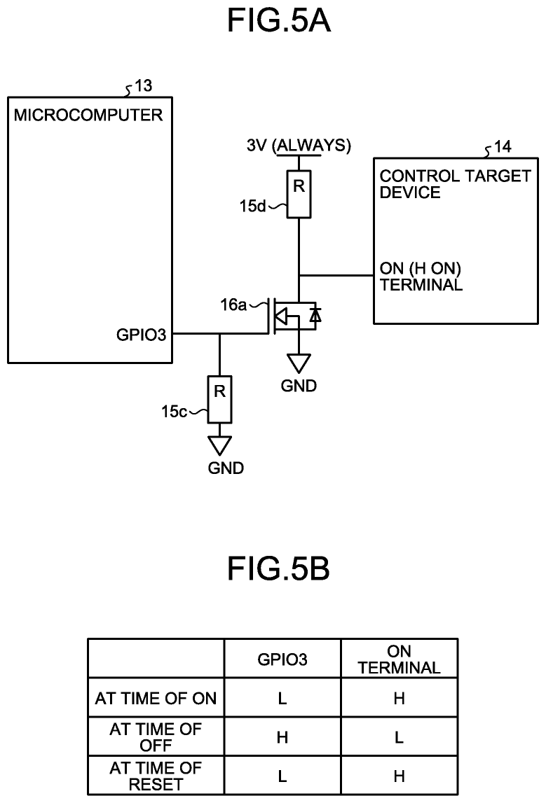

A first example of a circuit, in which the state of the connection destination is maintained when the level of the GPIO terminal in an indefinite period is a low level and the level of the connection destination of the microcomputer 13 at the time of occurrence of reset is a high level, is described with the GPIO3 with reference to FIGS. 5A and 5B.

FIG. 5A is a diagram illustrating a third example of the circuit that connects the microcomputer 13 in the embodiment and the control target device 14. When the microcomputer 13 is reset, the GPIO3 (third terminal) becomes a state of Low and is required to maintain, at a high level, signals from a connected terminal of the control target device 14.

The GPIO3 is connected to a gate of a first negative-channel metal oxide semiconductor (NMOS) transistor 16a, and an electric potential between the GPIO3 and the gate of the first NMOS transistor 16a is pulled down by a second pull-down resistor 15c. A source of the first NMOS transistor 16a is connected to GND (ground). A drain of the first NMOS transistor 16a is connected to a terminal of the control target device 14.

An electric potential between the drain of the first NMOS transistor 16a and the terminal of the control target device 14 is pulled up by a second pull-up resistor 15d.

FIG. 5B is a diagram illustrating a state of the terminal in the circuit in FIG. 5A corresponding to each state of the microcomputer 13 in the embodiment. Even if reset is executed from the microcomputer 13 against the control target device 14 (GPIO3=L) while the microcomputer 13 is ON, the level of an ON terminal is a high level because the gate of the first NMOS transistor 16a is kept at an opened state.

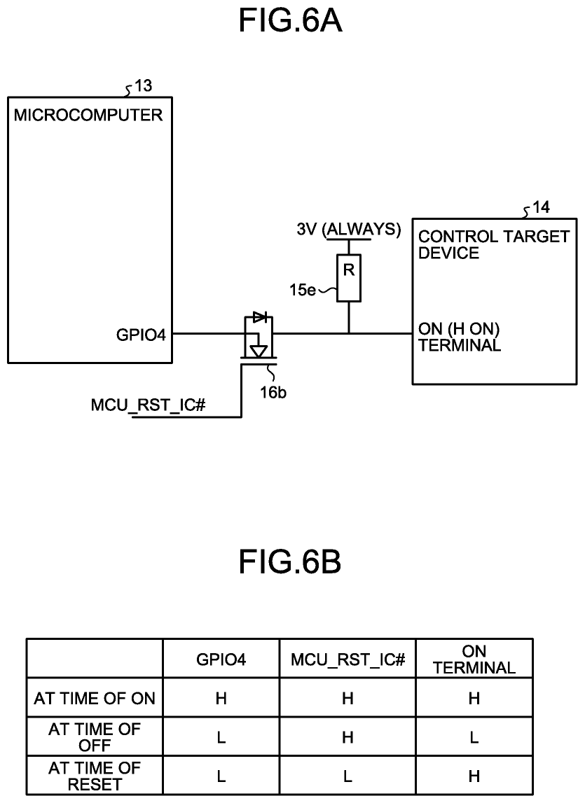

Next, a second example of a circuit, in which the state of the connection destination is maintained when the level of the GPIO terminal in an indefinite period is a low level and the level of the connection destination of the microcomputer 13 at the time of occurrence of reset is a high level, is described with the GPIO3 with reference to FIGS. 6A and 6B.

FIG. 6A is a diagram illustrating a fourth example of the circuit that connects the microcomputer 13 in the embodiment and the control target device 14. When the microcomputer 13 is reset, the GPIO4 (fourth terminal) is disconnected and is required to maintain, at a high level, signals from a connected terminal of the control target device 14. In an example in FIG. 6A, by mounting a second NMOS transistor 16b, it is possible to prevent an unnecessary current from being drawn into the control target device 14 in the case where the GPIO4 becomes low at the time of indefinite.

The GPIO4 is connected to a source of the second NMOS transistor 16b. A gate of the second NMOS transistor 16b receives a reset signal (MCU_RST_IC#) with which reset is performed at a state of Low. A drain of the second NMOS transistor 16b is connected to a terminal of the control target device 14. An electric potential between the drain of the second NMOS transistor 16b and the terminal of the control target device 14 is pulled up by a third pull-up resistor 15e.

FIG. 6B is a diagram indicating a state of the terminal in the circuit in FIG. 6A corresponding to each state of the microcomputer 13 in the embodiment. When reset has not been executed against the microcomputer 13 (MCU_RST_IC#=H), the gate of the second NMOS transistor 16b is closed. When reset is executed against the microcomputer 13 (MCU_RST_IC#=L), the gate of the second NMOS transistor 16b opens, and the GPIO4 and the control target device are disconnected.

Fourth Pattern (Resistor Pull-Down+FET Switch)

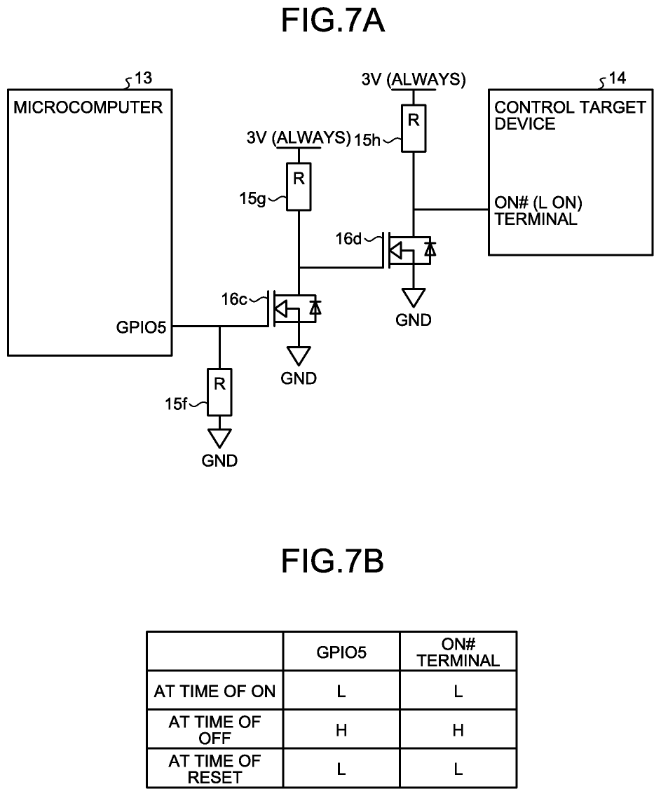

An example of a circuit, in which the state of the connection destination is maintained when the level of the GPIO terminal in an indefinite period is a low level and the level of the connection destination of the microcomputer 13 at the time of occurrence of reset is a low level, is described with the GPIO5 with reference to FIGS. 7A and 7B.

FIG. 7A is a diagram illustrating a fifth example of the circuit that connects the microcomputer 13 in the embodiment and the control target device 14. When the microcomputer 13 is reset, the GPIO5 (fifth terminal) becomes a state of Low and is required to maintain signals from a connected terminal of the control target device 14 at a low level.

The GPIO5 is connected to a gate of a third NMOS transistor 16c. An electric potential between the GPIO5 and the gate of the third NMOS transistor 16c is pulled down by a third pull down resistor 15f. A source of the third NMOS transistor 16c is connected to GND. A drain of the third NMOS transistor 16c is connected to a gate of a fourth NMOS transistor 16d. An electric potential between the drain of the third NMOS transistor 16c and the gate of the fourth NMOS transistor 16d is pulled up by a fourth pull-up resistor 15g. A source of the fourth NMOS transistor 16d is connected to GND. A drain of the fourth NMOS transistor 16d is connected to a terminal of the control target device 14. An electric potential between the drain of the fourth NMOS transistor 16d and the terminal of the control target device 14 is pulled up by a fifth pull-up resistor 15h.

FIG. 7B is a diagram indicating a state of the terminal in the circuit in FIG. 7A corresponding to each state of the microcomputer 13 in the embodiment. Even if reset is executed from the microcomputer 13 against the control target device 14 while the microcomputer 13 is ON (GPIO5=L), the level of an ON terminal becomes a low level because the gate of the third NMOS transistor 16c opens and the gate of the fourth NMOS transistor 16d closes.

Next, an example of a delay circuit to be connected to the MCU_RST_IC# of the microcomputer 13 will be described.

FIG. 8 is a diagram illustrating an example of a delay circuit 20 that delays a reset release signal (MCU_RST_IC#=H) to be input into the microcomputer 13 in the embodiment. The delay circuit 20 delays a reset release signal to be input to the microcomputer 13. Specifically, the reset release is performed on the microcomputer 13 after the delay circuit 20 supplies electric power to an integrated circuit (IC) of the system 142 side. With this delay, a voltage is applied to the ON terminal before electric power is supplied to the IC of the system 142 side, so that the system 142 is prevented from being unstable and the IC is prevented from breaking down. A delay time can be changed by changing capacitance of a capacitor connected to a CT terminal.

As described above, the information processing apparatus 10 of the embodiment includes the control device (microcomputer 13) that is reset upon receipt of a reset signal and the control target device 14 that is controlled by a signal transmitted from a terminal of the control device. The control device includes the first terminal (GPIO1) and the second terminal (GPIO2). When the control device (13) is reset, the first terminal (GPIO1) becomes a floating state and is required to maintain signals from a connected terminal of the control target device 14 at a high level. When the control device (13) is reset, the second terminal (GPIO2) becomes a floating state and is required to maintain signals from a connected terminal of the control target device 14 at a low level. The information processing apparatus 10 includes the first pull-up resistor 15a and the first pull-down resistor 15b. The first pull-up resistor 15a pulls up an electric potential at the first terminal (GPIO1). The first pull-down resistor 15b pulls down an electric potential at the second terminal (GPIO2).

With such configuration, even when the control device (13) being used for the control of the system 142 is reset, the system 142 can be operated continuously. That is, at the time of the reset of the control device (13), the control target device 14 (or system 142) will not stop, and this makes it possible to provide a reliable system. Moreover, because the information processing apparatus 10 is implemented without being given redundancy, such as double mounting of a microcomputer and mounting of an electrically erasable programmable read-only memory (EEPROM) to make data retract, it is possible to reduce cost as compared with the conventional method.

Moreover, in the information processing apparatus 10 of the embodiment, the control device (13) further includes the third terminal (GPIO3). When the control device (13) is reset, the third terminal (GPIO3) becomes a state of Low and is required to maintain signals from a connected terminal of the control target device 14 at a high level. The third terminal (GPIO3) is connected to the gate of the first NMOS transistor 16a. A source of the first NMOS transistor 16a is connected to GND. A drain of the first NMOS transistor 16a is connected to a terminal of the control target device 14. The second pull-down resistor 15c pulls down an electric potential between the third terminal (GPIO3) and the gates of the first NMOS transistor 16a. The second pull-up resistor 15d pulls up an electric potential between the drain of the first NMOS transistor 16a and the terminal of the control target device 14.

With such a configuration, even when the control device (13) is reset, it is possible to maintain, at a high level, signals from a terminal of the control target device 14, where the terminal is connected to a terminal that becomes a state of Low.

Moreover, in the information processing apparatus 10 of the embodiment, the control device (13) further includes the fourth terminal (GPIO4). When the control device (13) is reset, the fourth terminal (GPIO4) is disconnected and is required to maintain, at a high level, signals from a connected terminal of the control target device 14. The fourth terminal (GPIO4) is connected to the source of the second NMOS transistor 16b. The gate of the second NMOS transistor 16b receives a reset signal with which reset is performed at a state of Low. A drain of the second NMOS transistor 16b is connected to a terminal of the control target device 14. The third pull-up resistor 15e pulls up an electric potential between the drain of the second NMOS transistor 16b and the terminal of the control target device 14.

With such a configuration, even when the control device (13) is reset, it is possible to maintain, at a high level, signals from a terminal of the control target device 14, where the terminal is connected to a terminal to be disconnected from the control target device 14.

Moreover, in the information processing apparatus 10 of the embodiment, the control device (13) further includes a fifth terminal (GPIO5). When the control device (13) is reset, the fifth terminal (GPIO5) becomes a state of Low and is required to maintain, at a low level, signals from a connected terminal of the control target device 14. The fifth terminal (GPIO5) is connected to the gate of the third NMOS transistor 16c. A source of the third NMOS transistor 16c is connected to GND. A drain of the third NMOS transistor 16c is connected to the gate of the fourth NMOS transistor 16d. A source of the fourth NMOS transistor 16d is connected to GND. A drain of the fourth NMOS transistor 16d is connected to a terminal of the control target device 14. The third pull-down resistor 15f pulls down an electric potential between the fifth terminal (GPIO5) and the gate of the third NMOS transistor 16c. The fourth pull-up resistor 15g pulls up an electric potential between the drain of the third NMOS transistor 16c and the gates of the fourth NMOS transistor 16d. The fifth pull-up resistor 15h pulls up an electric potential between the drain of the fourth NMOS transistor 16d and the terminals of the control target device 14.

With such a configuration, even when the control device (13) is reset, it is possible to maintain, at a low level, signals from a terminal of the control target device 14, where the terminal is connected to a terminal that becomes a state of Low.

Moreover, in the information processing apparatus 10 in the embodiment, the first terminal (GPIO1) is connected to a terminal of the power source circuit 141 that supplies electric power to the system 142 that executes predetermined processing. The second terminal (GPIO2) is connected to a terminal of the system 142.

With such a configuration, even when the control device (13) is reset, the power source circuit 141 and the system 142 can be operated continuously because the state of each of the first terminal (GPIO1) and the second terminal (GPIO2) can be maintained at a state before the reset occurs.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. An information processing apparatus comprising:
a control device that is reset upon receipt of a reset signal; and
a control target device that is controlled by a signal sent from a terminal of the control device, wherein
the control device includes a fourth terminal that, when the control device is reset, is disconnected and is required to maintain signals from a connected terminal of the control target device at a high level,
the fourth terminal is connected to a source of a second NMOS transistor, the NMOS is a negative-channel metal oxide semiconductor,
a gate of the second NMOS transistor receives a reset signal with which reset is performed at a state of Low,
a drain of the second NMOS transistor is connected to a terminal of the control target device, and
the information processing apparatus further comprises:
a third pull-up resistor that pulls up an electric potential between the drain of the second NMOS transistor and the terminal of the control target device.

2. An information processing apparatus comprising:
a control device that is reset upon receipt of a reset signal; and
a control target device that is controlled by a signal sent from a terminal of the control device, wherein
the control device includes a fifth terminal that, when the control device is reset, becomes a state of Low and is required to maintain signals from a connected terminal of the control target device at a low level,
the fifth terminal is connected to a gate of a third NMOS transistor, the NMOS is a negative-channel metal oxide semiconductor,
a source of the third NMOS transistor is connected to ground, and
a drain of the third NMOS transistor is connected to a gate of a fourth NMOS transistor,
a source of the fourth NMOS transistor is connected to ground,
a drain of the fourth NMOS transistor is connected to a terminal of the control target device, and
the information processing apparatus further comprises:
a third pull-down resistor that pulls down an electric potential between the fifth terminal and the gate of the third NMOS transistor;
a fourth pull-up resistor that pulls up an electric potential between the drain of the third NMOS transistor and the gate of the fourth NMOS transistor; and
a fifth pull-up resistor that pulls up an electric potential between the drain of the fourth NMOS transistor and the terminal of the control target device.

3. The information processing apparatus according to claim 1, wherein
the control device includes:
a first terminal that, when the control device is reset, becomes a floating state and is required to maintain signals from the connected terminal at a high level; and
a second terminal that, when the control device is reset, becomes a floating state and is required to maintain signals from the connected terminal at a low level, and
the information processing apparatus further comprises:
a first pull-up resistor that pulls up an electric potential at the first terminal; and
a first pull-down resistor that pulls down an electric potential at the second terminal.

4. The information processing apparatus according to claim 1, wherein
the control device further includes a third terminal that, when the control device is reset, becomes a state of Low and is required to maintain signals from the connected terminal at a high level,
the third terminal is connected to a gate of a first NMOS transistor, the NMOS is a negative-channel metal oxide semiconductor,
a source of the first NMOS transistor is connected to ground, and
a drain of the first NMOS transistor is connected to a terminal of the control target device, and
the information processing apparatus further comprises:
a second pull-down resistor that pulls down an electric potential between the third terminal and the gate of the first NMOS transistor; and
a second pull-up resistor that pulls up an electric potential between the drain of the first NMOS transistor and the terminal of the control target device.

5. The information processing apparatus according to claim 3, wherein
the control target device includes
a system that executes predetermined processing, and
a power source circuit that supplies electric power to the system, the first terminal is connected to a terminal of the power source circuit, and the second terminal is connected to a terminal of the system.

6. The information processing apparatus according to claim 2, wherein
the control device includes:
a first terminal that, when the control device is reset, becomes a floating state and is required to maintain signals from the connected terminal at a high level; and
a second terminal that, when the control device is reset, becomes a floating state and is required to maintain signals from the connected terminal at a low level, and
the information processing apparatus further comprises:
a first pull-up resistor that pulls up an electric potential at the first terminal; and
a first pull-down resistor that pulls down an electric potential at the second terminal.

7. The information processing apparatus according to claim 2, wherein
the control device further includes a third terminal that, when the control device is reset, becomes a state of Low and is required to maintain signals from the connected terminal at a high level,
the third terminal is connected to a gate of a first NMOS transistor, the NMOS is a negative-channel metal oxide semiconductor,
a source of the first NMOS transistor is connected to ground, and
a drain of the first NMOS transistor is connected to a terminal of the control target device, and
the information processing apparatus further comprises:
a second pull-down resistor that pulls down an electric potential between the third terminal and the gate of the first NMOS transistor; and
a second pull-up resistor that pulls up an electric potential between the drain of the first NMOS transistor and the terminal of the control target device.

8. The information processing apparatus according to claim 6, wherein
the control target device includes
a system that executes predetermined processing, and
a power source circuit that supplies electric power to the system,
the first terminal is connected to a terminal of the power source circuit, and
the second terminal is connected to a terminal of the system.
